(19) United States
(12) Patent Application Publication
(10) Pub. No.: US 2022/0146940 A1
(43) Pub. Date: May 12, 2022

(54) COMPOSITION, SILICON-CONTAINING FILM, METHOD OF FORMING SILICON-CONTAINING FILM, AND METHOD OF TREATING SEMICONDUCTOR SUBSTRATE

(71) Applicant: JSR CORPORATION, Tokyo (JP)

(72) Inventors: Tatsuya KASAI, Tokyo (JP); Tomohiro Matsuki, Tokyo (JP); Yusuke Anno, Tokyo (JP); Tomoaki Seko, Tokyo (JP); Tatsuya Sakai, Tokyo (JP)

(73) Assignee: JSR CORPORATION, Tokyo (JP)

(21) Appl. No.: 17/584,456

(22) Filed: Jan. 26, 2022

Related U.S. Application Data
(63) Continuation of application No. PCT/JP2020/027257, filed on Jul. 13, 2020.

(30) Foreign Application Priority Data
Jul. 29, 2019 (JP) 2019-139238
Mar. 2, 2020 (JP) 2020-035378

(51) Int. Cl. G03F 7/11; C08G 77/50; C08G 77/26; C09D 183/08; H01L 21/027

(52) U.S. Cl. CPC G03F 7/11; C08G 77/50; H01L 21/0273; C09D 183/08; C08G 77/26

(57) ABSTRACT

A composition includes a solvent and at least one compound selected from the group consisting of: a first compound which comprises a first structural unit comprising a Si—H bond, and a second structural unit represented by formula (2), and a second compound which comprises the second structural unit represented by the formula (2). X represents a monovalent organic group having 1 to 20 carbon atoms which comprises a nitrogen atom; e is an integer of 1 to 3; R⁴ represents a monovalent organic group having 1 to 20 carbon atoms, or a hydroxy group, a hydrogen atom, or a halogen atom; and f is an integer of 0 to 2. A sum of e and f is no greater than 3. In the case where the at least one compound is the second compound, f is 1 or 2, and at least one R⁴ represents a hydrogen atom.

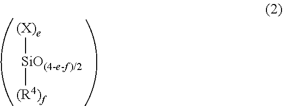

### CROSS-REFERENCE TO RELATED APPLICATIONS

The present application is a continuation application of International Application No. PCT/JP2020/02757, filed Jul. 13, 2020, which claims priority to Japanese Patent Application No. 2019-139238 filed Jul. 29, 2019, and to Japanese Patent Application No. 2020-035378 filed Mar. 2, 2020. The contents of these applications are incorporated herein by reference in their entirety.

### BACKGROUND OF THE INVENTION

### Field of the Invention

The present invention relates to a composition, a silicon-containing film, a method of forming a silicon-containing film, and a method of treating a semiconductor substrate.

### Discussion of the Background

In pattern formation in production of semiconductor substrates, for example, a multilayer resist process is employed which includes: exposing and developing a resist film laminated via an organic underlayer film, a silicon-containing film, and the like on a substrate; and using as a mask, a resist pattern thus obtained to carry out etching, whereby a substrate is formed having a pattern formed thereon (see PCT International Publication No. 2012/039337).

### SUMMARY OF THE INVENTION

According to an aspect of the present invention, a composition includes: a solvent; and at least one compound selected from the group consisting of: a first compound which includes a first structural unit including a Si—H bond, and a second structural unit represented by formula (2), and a second compound which includes the second structural unit represented by the formula (2).

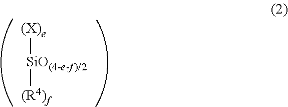

In the formula (2), X represents a monovalent organic group having 1 to 20 carbon atoms which includes a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; and f is an integer of 0 to 2, wherein in a case in which f is 2, two R⁴s are identical or different from each other, and wherein a sum of e and f is no greater than 3. In the case in which the at least one compound is the second compound, f is 1 or 2, and at least one R⁴ represents a hydrogen atom.

According to another aspect of the present invention, a silicon-containing film is formed from the above-mentioned composition.

According to a further aspect of the present invention; a method of forming a silicon-containing film includes applying a silicon-containing-film-forming composition directly or indirectly on a substrate. The silicon-containing-film-forming composition includes a solvent; and at least one compound selected from the group consisting of: a first compound which includes a first structural unit including a Si—H bond, and a second structural unit represented by formula (2); and a second compound which includes the second structural unit represented by the formula (2).

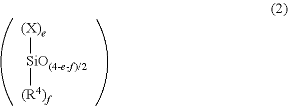

In the formula (2), X represents a monovalent organic group having 1 to 20 carbon atoms which includes a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; and f is an integer of 0 to 2, wherein in a case in which f is 2, two R⁴s are identical or different from each other, and wherein a sum of e and f is no greater than 3. In the case in which the at least one compound is the second compound, f is 1 or 2, and at least one R⁴ represents a hydrogen atom.

According to a further aspect of the present invention, a method of treating a semiconductor substrate includes: applying a silicon-containing-film-forming composition directly or indirectly on a substrate to form a silicon-containing film; and removing the silicon-containing film, with a removing liquid including an acid. The silicon-containing-film-forming composition incudes: a solvent; and at least one compound selected from the group consisting of: a first compound which includes a first structural unit including a Si—H bond, and a second structural unit represented by formula (2); and a second compound which includes the second structural unit represented by the formula (2).

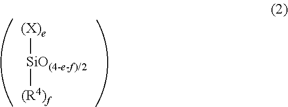

In the formula (2), X represents a monovalent organic group having 1 to 20 carbon atoms which includes a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; and f is an integer of 0 to 2, wherein in a case in which f is 2, two R⁴s are identical or different from each other, and wherein a sum of e and f is no greater than 3. In the case in which the at least one compound is the second compound, f is 1 or 2, and at least one R⁴ represents a hydrogen atom.

### DESCRIPTION OF EMBODIMENTS

Resistance to etching by an oxygen-based gas is required for a silicon-containing film to be used in a multilayer resist process in a step of producing a semiconductor substrate or the like.

In a process of removing the silicon-containing from in the step of producing the semiconductor substrate or the like, a procedure of using a removing liquid containing an acid is conceivable as a procedure of removing the silicon-containing film while limiting damage to the substrate.

According to one embodiment of the invention s, a composition contains: at least one compound selected from the group consisting of: a first compound (hereinafter, may be also referred to as “(A1) compound” or “compound (A1)”) which has a first structural unit (hereinafter, may be also referred to as “structural unit (I)”) including a Si—H bond, and a second structural unit (hereinafter, may be also referred to as “structural unit (II)”) represented by the following formula (2), and a second compound (hereinafter, may be also referred to as “(A2) compound” or “compound (A2)”) which has the second structural unit represented by the following formula (2), (hereinafter, the compound (A1) and the compound (A2) may be also referred to collectively as “compound (A)”); and a solvent (hereinafter, may be also referred to as “(B) solvent” or “solvent (B)”),

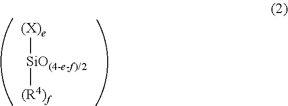

wherein, in the formula (2), X represents a monovalent organic group having 1 to 20 carbon atoms which contains a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; and f is an integer of 0 to 2, wherein in a case in which f is 2, two R⁴s are identical or different from each other, and wherein a sum of e and f is no greater than 3, wherein

in the case in which the at least one compound is the second compound, f is 1 or 2, and at least one R⁴ represents a hydrogen atom.

Another embodiment of the invention s is a silicon-containing film formed from the composition of the one embodiment of the invention.

According to still another embodiment of the invention, a method of forming a silicon-containing film includes: applying a silicon-containing-film-forming composition directly or indirectly on a substrate, wherein the silicon-containing-film-forming composition contains: the compound (A); and the solvent (B).

According to yet another embodiment of the invention, a method of treating a semiconductor substrate includes: applying a silicon-containing-film-forming composition directly or indirectly on a substrate; and removing a silicon-containing film formed in the applying, with a removing liquid containing an acid, wherein the silicon-containing-film-forming composition contains: the compound (A); and the solvent (B).

The composition of the one embodiment of the present invention enables forming the silicon-containing film being superior in terms of resistance to etching by an oxygen-based gas. Furthermore, the composition enables forming a silicon-containing film which is superior in terms of removability of the silicon-containing film (hereinafter, may be also referred to as “film removability”) by a removing liquid containing an acid. The silicon-containing film of the other embodiment of the present invention is superior in terms of resistance to etching by an oxygen-based gas and film removability. The method of forming a silicon-containing film of the still another embodiment of the present invention enables forming a silicon-containing film which is superior in terms of resistance to etching by an oxygen-based gas and film removability. The method of treating a semiconductor substrate of the yet another embodiment of the present invention enables easily removing a silicon-containing film in a removing step thereof, while limiting damage to layer(s) under the silicon-containing film due to etching. Thus, these can be suitably used in production of a silicon substrate, and the like.

Hereinafter, the composition, the silicon-containing film, the method of forming a silicon-containing film, and the method of treating a semiconductor substrate of the embodiments of the present invention will be explained in detail.

### Composition

A composition of one embodiment of the present invention contains the compound (A) and the solvent (B). The composition may also contain other optional components within a range not leading to impairment of the effects of the present invention.

Due to containing the compound (A) and the solvent (B), the composition enables forming a silicon-containing film which is superior in terms of resistance to etching by an oxygen-based gas. Furthermore, the composition enables forming the silicon-containing film being superior in terms of film removability. Although not necessarily clarified and without wishing to be bound by any theory, the reason for achieving the aforementioned effects by the composition due to involving such a constitution may be presumed, for example, as in the following. It is considered that due to the compound (A) having a Si—H bond, a proportion of silicon contained in and/or a film density of the silicon-containing film can be increased, thereby enabling improving resistance to etching by an oxygen-based gas. Furthermore, it is considered that due to the compound (A) having the structural unit (II), hydrophilicity of the silicon-containing film can be enhanced, whereby film removability can be improved.

In addition to the above effects, the composition also enables forming the silicon-containing film being superior in terms of an embedding property. The reason for the composition achieving such an effect is surmised to be as follows: due to the composition (A) having the structural unit (II), film shrinkage of the silicon-containing film is inhibited, thereby enabling improving the embedding property.

Due to enabling forming the silicon-containing film being superior in terms of resistance to etching by an oxygen-based gas and film removability, the composition can be suitably used as a composition for forming a silicon-containing film (i.e., a silicon-containing-film-forming composition). Furthermore, the composition can be suitably used in a semiconductor substrate-producing process. Specifically, the composition can be suitably used as a composition for forming a silicon-containing film as a resist underlayer film in a multilayer resist process. Moreover, due to containing a nitrogen atom, the composition can be suitably used as a composition for forming a silicon-containing film as an etching stopper film in a dual damascene process, and the like.

Each component contained in the composition is described below.

(A) Compound

The compound (A) is at least one compound selected from the group consisting of the compound (A1) and the compound (A2). The compound (A) may be used alone as one type, or in a combination of two or more types thereof.

(A1) Compound

The compound (A1) has the structural unit (I) and the structural unit (II). The compound (A1) may have other structural unit(s) aside from the structural unit (I) and the structural unit (II). The compound (A1) may be used alone as one type, or in a combination of two or more types thereof.

Each structural unit contained in the compound (A1) is described below.

Structural Unit (I)

The structural unit (I) includes a Si—H bond. The structural unit (I) may be exemplified by at least one structural unit selected from the group consisting of a structural unit represented by the following formula (1-1), and a structural unit represented by the following formula (1-2).

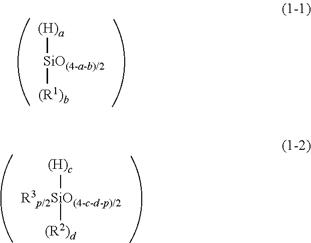

In the above formula (1-1), a is an integer of 1 to 3; R¹ represents a monovalent organic group having 1 to 20 carbon atoms, or a hydroxy group or a halogen atom; and b is an integer of 0 to 2, wherein in a case in which b is 2, two R¹s are identical or different from each other, and wherein a sum of a and b is no greater than 3.

In the above formula (1-2), is an integer of 1 to 3; R² represents a monovalent organic group having 1 to 20 carbon atoms, or a hydroxy group or a halogen atom; d is an integer of 0 to 2, wherein in a case in which d is 2, two R²s are identical or different from each other; R³ represents a substituted or unsubstituted divalent hydrocarbon group having 1 to 20 carbon atoms which bonds to two silicon atoms; and p is an integer of 1 to 3, wherein in a case in which p is no less than 2, a plurality of R³s are identical or different from each other, and wherein a sum of c, d, and p is no greater than 4.

The “organic group” as referred to herein means a group that includes at least one carbon atom. The monovalent organic group having 1 to 20 carbon atoms which may be represented by R¹ or R² is exemplified by: a monovalent hydrocarbon group having 1 to 20 carbon atoms; a monovalent group having 1 to 20 carbon atoms that contains a divalent hetero atom-containing group between two adjacent carbon atoms of the monovalent hydrocarbon group; a monovalent group having 1 to 20 carbon atoms obtained by substituting with a monovalent hetero atom-containing group, a part or all of hydrogen atoms included in the monovalent hydrocarbon group or the group that contains a divalent hetero atom-containing group; a monovalent group containing —O— in combination with the monovalent hydrocarbon group having 1 to 20 carbon atoms; the monovalent group having 1 to 20 carbon atoms that contains a divalent hetero atom-containing group between two adjacent carbon atoms of the monovalent hydrocarbon group, or the monovalent group having 1 to 20 carbon atoms obtained by substituting with a monovalent hetero atom-containing group, a part or all of hydrogen atoms included in the monovalent hydrocarbon group or the group that contains a divalent hetero atom-containing group; and the like.

Exemplary monovalent hydrocarbon groups containing 1 to 20 carbon atoms include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include: alkyl groups such as a methyl group and an ethyl group; alkenyl groups such as an ethenyl group; alkynyl groups such as an ethynyl group; and the like.

Examples of the monovalent alicyclic hydrocarbon group having 3 to 20 carbon atoms include: monovalent monocyclic alicyclic saturated hydrocarbon groups such as a cyclopentyl group and a cyclohexyl group; monovalent monocyclic alicyclic unsaturated hydrocarbon groups such as a cyclopentenyl group and a cyclohexenyl group; monovalent polycyclic alicyclic saturated hydrocarbon groups such as a norbornyl group and an adamantyl group; monovalent polycyclic alicyclic unsaturated hydrocarbon groups such as a norbornenyl group and a tricyclodecenyl group; and the like.

Examples of the monovalent aromatic hydrocarbon group having 6 to 20 carbon atoms include: aryl groups such as a phenyl group, a tolyl group, a xylyl group, a naphthyl group, a methylnaphthyl group, and an anthryl group; aralkyl groups such as a benzyl group, a naphthylmethyl group, and an anthrylmethyl group; and the like.

The hetero atom constituting the divalent hetero atom-containing group or the monovalent hetero atom-containing group is exemplified by an oxygen atom, a nitrogen atom, a sulfur atom, a phosphorus atom, a silicon atom, a halogen atom, and the like. Examples of the halogen atom include a fluorine atom, a chlorine atom, a bromine atom, an iodine atom, and the like.

Examples of the divalent hetero atom-containing group include —O—, —CO—, —S—, —CS—, —NR′—, a combination of two or more of these, and the like, wherein R′ represents a hydrogen atom or a monovalent hydrocarbon group. Of these, —O— or —S— is preferred.

Examples of the monovalent hetero atom-containing group include a halogen atom, a hydroxy group, a carboxy group, a cyano group, an amino group, a sulfanyl group, and the like.

The number of carbon atoms in the monovalent organic group which may be represented by R¹ or R² is preferably 1 to 10, and more preferably 1 to 6.

The halogen atom which may be represented by R¹ or R² is preferably a chlorine atom.

R¹ and R² each represent preferably the monovalent chain hydrocarbon group, the monovalent aromatic hydrocarbon group, or the monovalent group obtained by substituting with a monovalent hetero atom-containing group, a part or all of hydrogen atoms included in the monovalent hydrocarbon group; more preferably the alkyl group or the aryl group; still more preferably a methyl group, an ethyl group, or a phenyl group; and particularly preferably a methyl group or an ethyl group.

The substituted or unsubstituted divalent hydrocarbon group having 1 to 20 carbon atoms that bonds to two Si atoms which is represented by R³ is exemplified by a substituted or unsubstituted divalent chain hydrocarbon group having 1 to 20 carbon atoms, a substituted or unsubstituted divalent aliphatic cyclic hydrocarbon group having 3 to 20 carbon atoms, a substituted or unsubstituted divalent aromatic hydrocarbon group having 6 to 20 carbon atoms, and the like.

Examples of the unsubstituted divalent chain hydrocarbon group having 1 to 20 carbon atoms include: chain saturated hydrocarbon groups such as a methanediyl group and an ethanediyl group; chain unsaturated hydrocarbon groups such as an ethenediyl group and a propenediyl group; and the like.

Examples of the unsubstituted divalent aliphatic cyclic hydrocarbon group having 3 to 20 carbon atoms include: monocyclic saturated hydrocarbon groups such as a cyclobutanediyl group; monocyclic unsaturated hydrocarbon groups such as a cyclobutenediyl group; polycyclic saturated hydrocarbon groups such as a bicyclo[2.2.1]heptanediyl group; polycyclic unsaturated hydrocarbon groups such as a bicyclo[2.2.1]heptenediyl group; and the like.

Examples of the unsubstituted divalent aromatic hydrocarbon group having 6 to 20 carbon atoms include a phenylene group, a biphenylene group, a phenyleneethylene group, a naphthylene group, and the like.

Examples of a substituent in the substituted divalent hydrocarbon group having 1 to 20 carbon atoms which may be represented by R³ include a halogen atom, a hydroxy group, a cyano group, a nitro group, an alkoxy group, an acyl group, an acyloxy group, and the like.

R³ represents preferably the unsubstituted chain saturated hydrocarbon group or the unsubstituted aromatic hydrocarbon group, and more preferably a methanediyl group, an ethanediyl group, or a phenylene group.

a is preferably 1 or 2, and more preferably 1.

b is preferably 0 or 1, and more preferably 0.

c is preferably 1 or 2, and more preferably 1.

d is preferably 0 or 1, and more preferably 0.

p is preferably 2 or 3.

The lower limit of a proportion of the structural unit (I) contained with respect to total structural units constituting the compound (A) is preferably 1 mol %, more preferably 10 mol %, still more preferably 30 mol %, and particularly preferably 50 mol %. The upper limit of the proportion is preferably 99 mol %, more preferably 90 mol %, still more preferably 80 mol %, and particularly preferably 70 mol %. When the proportion of the structural unit (I) falls within the above range, resistance to etching by an oxygen-based gas can be further improved.

Structural Unit (II)

The structural unit (II) is represented by the following formula (2).

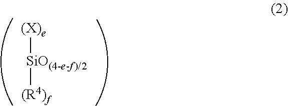

In the above formula (2), X represents a monovalent organic group having 1 to 20 carbon atoms which contains a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; f is an integer of 0 to 2, wherein in a case in which f is 2, two les are identical or different from each other, and wherein a sum of e and f is no greater than 3.

The monovalent organic group having 1 to 20 carbon atoms which contains a nitrogen atom and is represented by X (hereinafter, may be also referred to as “nitrogen atom-containing group (X)”) is preferably a group which includes a cyano group, a group which includes an isocyanate group, or a group represented by the following formula (2-3) or (2-4), and more preferably a group which includes a cyano group, a group which includes an isocyanate group, or a group represented by the following formula (2-4). When the structural unit (II) includes the nitrogen atom-containing group (X), the film removability of the silicon-containing film formed from the composition can be improved. Furthermore, when the structural unit (II) includes the nitrogen atom-containing group (X), the embedding property of the silicon-containing film formed from e composition can be improved.

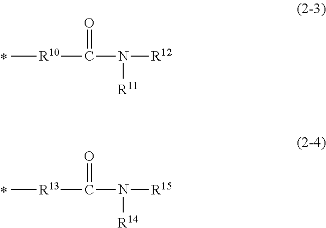

In the above formulae (2-3) and (2-4), * denotes a binding site to the silicon atom in the above formula (2).

In the above formula (2-3), R¹⁰ represents a single bond or a divalent organic group having 1 to 20 carbon atoms; and with regard to R¹¹ and R¹², R¹¹ represents a hydrogen atom or a monovalent hydrocarbon group having 1 to 20 carbon atoms, and R¹² represents a monovalent organic group having 1 to 20 carbon atoms, or R¹¹ and R¹² taken together represent a ring structure having 4 to 20 ring atoms together with the atom chain to which R¹¹ and R¹² bond.

In the above formula (2-4), R¹³ represents a single bond or a divalent organic group having 1 to 20 carbon atoms; and with regard to R¹⁴ and R¹⁵, R¹⁴ represents a hydrogen atom or a monovalent hydrocarbon group having 1 to 20 carbon atoms, and R¹⁵ represents a monovalent organic group having 1 to 20 carbon atoms, or R¹⁴ and R¹⁵ taken together represent a ring structure having 4 to 20 ring atoms together with the atom chain to which R¹⁴ and R¹⁵ bond.

The monovalent organic group which may be represented by R⁴ is exemplified by groups similar to the groups exemplified as the monovalent organic group having 1 to 20 carbon atoms in connection with R¹ in the above formula (1-1), and the like. R⁴ represents preferably the monovalent organic group having 1 to 20 carbon atoms, or a hydroxy group or a halogen atom.

e is preferably 1 or 2, and more preferably 1.

f is preferably 0 or 1, and more preferably 0.

Examples of the divalent organic group having 1 to 20 carbon atoms which may be represented by R¹⁰ or R¹³ include groups obtained by removing one hydrogen atom from each of the groups exemplified as the monovalent organic group having 1 to 20 carbon atoms in connection with R¹ in the above formula (1-1), and the like.

Examples of the monovalent hydrocarbon group having 1 to 20 carbon atoms which may be represented by R¹¹ or R¹⁴ include groups similar to the groups exemplified as the monovalent hydrocarbon group having 1 to 20 carbon atoms in connection with R¹ in the above formula (1-1), and the like.

Examples of the monovalent organic group having 1 to 20 carbon atoms which may be represented by R¹² or R¹⁵ include groups similar to groups exemplified as the monovalent organic group having 1 to 20 carbon atoms in connection with R¹ in the above formula (1-1), and the like.

Examples of the ring structure having 4 to 20 ring atoms constituted by R¹¹ and R¹² taken together, together with the atom chain to which R¹¹ and R¹² bond include nitrogen-containing heterocyclic structures such as a pyrrolidine structure and a piperidine structure, and the like.

Examples of the ring structure having 4 to 20 ring atoms constituted by R¹⁴ and R¹⁵ taken together, together with the atom chain to which R¹⁴ and R¹⁵ bond include lactam structures such as a β-propiolactam structure, a γ-butyrolactam structure, a δ-valerolactam structure, and an ε-caprolactam structure, and the like.

R¹⁰ represents preferably a divalent hetero atom-containing group, more preferably a divalent oxygen atom-containing group, and still more preferably *—CH₂—O, where * denotes a binding site to the silicon atom in the above formula (2).

R¹¹ and R¹⁴ each represent preferably a hydrogen atom or the monovalent hydrocarbon group having 1 to 20 carbon atoms, and more preferably a hydrogen atom.

R¹² represents preferably the monovalent hydrocarbon group having 1 to 20 carbon atoms, and more preferably a monovalent chain hydrocarbon group having 1 to 20 carbon atoms.

R¹³ represents preferably a divalent hydrocarbon group having 1 to 20 carbon atoms, more preferably a divalent chain hydrocarbon group having 1 to 20 carbon atoms, and still more preferably an n-propanediyl group.

R¹⁵ represents preferably a monovalent hetero atom-containing group, more preferably a monovalent oxygen atom-containing group, and still more preferably —O—CH₃.

Examples of the group which includes a cyano group include groups represented by the following formula (2-1), and the like.

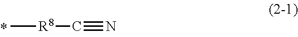

In the above formula (2-1), R⁸ represents a single bond or a divalent organic group having 1 to 20 carbon atoms; and * denotes a binding site to the silicon atom in the above formula (2).

Examples of the divalent organic group having 1 to 20 carbon atoms which may be represented by R⁸ include groups obtained by removing one hydrogen atom from the groups exemplified as the monovalent organic group having 1 to 20 carbon atoms in connection with R¹ in the above formula (1), and the like.

The number of carbon atoms in the divalent organic group which may be represented by R8 is preferably 1 to 10, and more preferably 1 to 5.

R⁸ represents preferably a divalent chain hydrocarbon group, more preferably an alkanediyl group, and still more preferably an ethanediyl group or an n-propanediyl group.

Examples of the group which includes an isocyanate group include groups represented by the following formula (2-2), and the like.

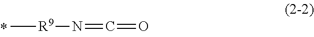

In the above formula (2-2), R⁹ represents a single bond or a divalent organic group having 1 to 20 carbon atoms; and * denotes a binding site to the silicon atom in the above formula (2).

Examples of the divalent organic group having 1 to 20 carbon atoms which may be represented by R⁹ include groups obtained by removing one hydrogen atom from the groups exemplified as the monovalent organic group having 1 to 20 carbon atoms in connection with R¹ in the above formula (1), and the like.

The number of carbon atoms in the divalent organic group which may be represented by R⁹ is preferably 1 to 10; and more preferably 1 to 5.

R⁹ represents preferably a divalent chain hydrocarbon group, more preferably an alkanediyl group, and still more preferably an n-propanediyl group.

The lower limit of a proportion of the structural unit (II) contained with respect to total structural units constituting the compound (A) is preferably 1 mol %, more preferably 5 mol %, still more preferably 10 mol %, and particularly preferably 20 mol %. The upper of the proportion is preferably 99 mol %, more preferably 90 mol %, still more preferably 80 mol %, and particularly preferably 70 mol %. When the proportion of the structural unit (II) falls within the above range, the film removability and the embedding property can be still further improved.

Other Structural Unit(s)

Examples of the other structural unit(s) include at least one third structural unit (hereinafter, r ray be also referred to as “structural unit (III)”) selected from the group consisting of a structural unit represented by the following formula (3-1) and a structural unit represented by the following formula (3-2), a structural unit which includes a Si—Si bond, and the like.

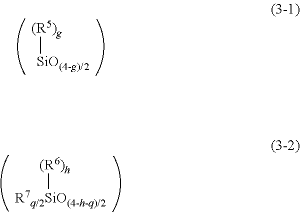

In the above formula (3-1), R⁵ represents a monovalent organic group having 1 to 20 carbon atoms, or a hydroxy group or a halogen atom; and g is an integer of 1 to 3, wherein in a case in which g is no less than 2, a plurality of R⁵s are identical or different from each other.

In the above formula (3-2), R⁶ represents a monovalent organic group having 1 to 20 carbon atoms, or a hydroxy group or a halogen atom; h is 1 or 2, wherein in a case in which h is 2, two R⁶s are identical or different from each other; R⁷ represents a substituted or unsubstituted divalent hydrocarbon group having 1 to 20 carbon atoms which bonds to two silicon atoms; and q is an integer of 1 to 3, wherein in a case in which q is no less than 2, a plurality of R's are identical or different from each other, and wherein a sum of h and q is no greater than 4.

Examples of the monovalent organic group having 1 to 20 carbon atoms which may be represented by R⁵ or R⁶ include groups similar to the groups exemplified as the monovalent organic group having 1 to 20 carbon atoms in connection with R′ in the above formula (1-1), and the like.

R⁵ and R⁶ each represent preferably the monovalent chain hydrocarbon group, the monovalent aromatic hydrocarbon group, or the monovalent group obtained by substituting with a monovalent hetero atom-containing group, a part or all of hydrogen atoms included in the monovalent hydrocarbon group; more preferably the alkyl group or the aryl group; still more preferably a methyl group, an ethyl group, or a phenyl group; and particularly preferably a methyl group or an ethyl group.

Examples of the substituted or unsubstituted divalent hydrocarbon group having 1 to 20 carbon atoms that bonds to two Si atoms which is represented by R⁷ include groups similar to those exemplified as the substituted or unsubstituted divalent hydrocarbon group having 1 to 20 carbon atoms that bonds to two Si atoms in connection with R³ in the above formula (1-2), and the like.

R⁷ represents preferably the unsubstituted chain saturated hydrocarbon group or unsubstituted aromatic hydrocarbon group, and more preferably a methanediyl group, an ethanediyl group, or a phenylene group.

g is preferably 1 or 2, and more preferably 1.

h is preferably 1.

q is preferably 2 or 3.

In a case in which the compound (A1) has the structural unit (III) as the other structural unit, the lower limit of a proportion of the structural unit (III) contained with respect to total structural units constituting the compound (A1) is preferably 1 mol %, more preferably 5 mol %, still more preferably 10 mol %, and particularly preferably 20 mol %. The upper limit of the proportion is preferably 90 mol %, more preferably 70 mol %, still more preferably 60 mol %, and particularly preferably 50 mol %.

(A2) Compound

The compound (A2) has a structural unit (the structural unit (II)) represented by the above formula (2), wherein in the above formula (2), f is 1 or 2, and at least one R⁴ represents a hydrogen atom.

The compound (A2) may have other structural unit(s) aside from the structural unit (II). The compound (A2) may be used alone of one type, or in a combination of two or more types thereof,

The structural unit (II) and the other structural unit(s) are described in the “(A1) Compound” section above.

The lower limit of a proportion of the compound (A) with respect to total components other than the solvent (B) in the composition is preferably 5% by mass, and more preferably 10% by mass. The upper limit of the proportion is preferably 99 mol %, and more preferably 50 mol %.

The compound (A) preferably has a form of a polymer. A “polymer” as referred to herein means a compound having no less than two structural units; in a case in which an identical structural unit repeats twice or more, this structural unit may be also referred to as a “repeating unit.” In the case in which the compound (A) has the form of a polymer, the lower limit of a polystyrene equivalent weight average molecular weight (Mw) of the compound (A) as determined by gel permeation chromatography is preferably 1,000, more preferably 1,300, still more preferably 1,500, and particularly preferably 1,800. The upper limit of the Mw is preferably 100,000, more preferably 20,000, still more preferably 7,000, and particularly preferably 3,000.

The Mw of the compound (A) herein is a value measured by gel permeation chromatography (GPC; detector: differential refractometer) using GPC columns available from Tosoh Corporation (“G2000 HXI”×2, “G3000 HXL”×1, and “G4000 HXL”×1) under analytical conditions involving a flow rate of 1.0 mL/min, an elution solvent of tetrahydrofuran, and a column temperature of 40° C., with mono-dispersed polystyrene as a standard.

For example, the compound (A) can be obtained by: carrying out hydrolytic condensation with a compound that gives the structural unit (I) and a compound that gives the structural unit (II), as well as, as necessary, other compound(s) that give the other structural unit(s), in a solvent in the presence of water and a catalyst such as oxalic acid; and preferably subjecting a solution including a thus generated hydrolytic condensation product to purification by solvent substitution or the like in the presence of a dehydrating agent such as orthoformic acid trimethyl ester. It is believed that by the hydrolytic condensation reaction or the like, respective monomer compounds are incorporated into the compound (A) regardless of a type thereof; and proportions of the structural units (I) and (II) and the other structural unit(s) in the thus synthesized compound (A) will typically be equivalent to proportions of the usage amounts of respective monomer compounds used in the synthesis reaction.

(B) Solvent

The solvent (B) is exemplified by an alcohol solvent, a ketone solvent, an ether solvent, an ester solvent, a nitrogen-containing solvent, water, and the like. The solvent (B) may be used either alone of one type, or in a combination of two or more types thereof.

Examples of the alcohol solvent include: monohydric alcohol solvents such as methanol, ethanol, n-propanol, iso-propanol, n-butanol, and iso-butanol; polyhydric alcohol solvents such as ethylene glycol, 1,2-propyleneglycol; diethylene glycol, and dipropylene glycol; and the like.

Examples of the ketone solvent include acetone, methyl ethyl ketone, methyl n-propyl ketone, methyl iso-butyl ketone, cyclohexanone, and the like.

Examples of the ether solvent include ethyl ether, isopropyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran, and the like.

Examples of the ester solvent include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, di propylene glycol monomethyl ether acetate, di propylene glycol monoethyl ether acetate, ethyl propionate, n-butyl propionate, methyl lactate, ethyl lactate, and the like.

Examples of the nitrogen-containing solvent include N,N-dimethylformamide, N,N-dimethylacetamide, N-methylpyrrolidone, and the like.

Of these, the ether solvent or the ester solvent is preferred, and due to superiority in film formability, the ether solvent having a glycol structure or the ester solvent having a glycol structure is more preferred.

Examples of the ether solvent having a glycol structure and the ester solvent having a glycol structure include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like. Of these, propylene glycol monomethyl ether acetate and propylene glycol monoethyl ether are preferred.

A proportion of the ether solvent having a glycol structure and the ester solvent having a glycol structure in the solvent (B) is preferably 20% by mass, more preferably 60% by mass, still more preferably 90% by mass, and particularly preferably 100% by mass.

The lower limit of a proportion of the solvent (B) in the composition is preferably 50% by mass, more preferably 80% by mass, still more preferably 90% by mass, and particularly preferably 95% by mass. The upper limit of the proportion is preferably 99.9% by mass, and more preferably 99% by mass.

Other Optional Component(s)

The other optional component(s) is/are exemplified by an acid generating agent (hereinafter, may be also referred to as “(C) acid generating agent” or “acid generating agent (C)”), an orthoester (hereinafter, may be also referred to as “(D) orthoester” or “orthoester (D)”), a basic compound (including a base generating agent), a radical generating agent, a surfactant, colloidal silica, colloidal alumina, an organic polymer, and the like. The other optional component(s) may be used alone of one type, or in a combination or two or more types thereof.

(C) Acid Generating Agent

The acid generating agent (C) is a component capable of generating an acid upon exposure or heating. When the composition contains the acid generating agent, the condensation reaction of the compound (A) can be promoted even at a relatively low temperature (including room temperature).

Examples of the acid generating agent capable of generating an acid upon exposure (hereinafter, may be also referred to as “photo acid generating agent”) include acid generating agents disclosed in paragraphs [0077] to [0081] of Japanese Unexamined Patent Application, Publication No. 2004-168748, as well as triphenylsulfonium trifluoromethanesulfonate and the like.

Examples of the acid generating agent capable of generating an acid upon heating (hereinafter, may be also referred to as “thermal acid generating agent”) include onium salt-type acid generating agents exemplified as the photo acid generating agent in the above-mentioned patent document, as well as 2,4,4,6-tetrabromocyclohexadienone, benzoin tosylate, 2-nitrobenzyl tosylate, alkyl sulfonates, and the like.

In the case in which the composition contains the acid generating agent (C), the upper limit of a content of the acid generating agent (C) with respect to 100 parts by mass of the compound (A) is preferably 100 parts by mass, more preferably 40 parts by mass, and still more preferably 30 parts by mass,

(D) Orthoester

The orthoester (D) is an ester of an orthocarboxylic acid. The orthoester (D) reacts with water to give a carboxylic acid ester or the like. Examples of the orthoester (D) include: orthoformic acid esters such as methyl orthoformate, ethyl orthoformate, and propyl orthoformate; orthoacetic acid esters such as methyl orthoacetate, ethyl orthoacetate, and propyl orthoacetate; orthopropionic acid esters such as methyl orthopropionate, ethyl orthopropionate, and propyl orthopropionate; and the like. Of these, the orthoester (D) is preferably the orthoformic acid ester, and more preferably trimethyl orthoformate.

In the case in which the composition contains the orthoester (D), the lower limit of a content of the orthoester (D) with respect to 100 parts by mass of the compound (A) is preferably 10 parts by mass, more preferably 100 parts by mass, still more preferably 200 parts by mass, and particularly preferably 300 parts by mass. The upper limit of the content is preferably 10,000 parts by mass, more preferably 5,000 parts by mass, still more preferably 2,000 parts by mass, and particularly preferably 1,000 parts by mass.

Preparation Procedure of Composition

A procedure of preparing the composition is not particularly limited, and the composition may be prepared by, for example, mixing at a predetermined ratio, a solution of the compound (A) the solvent (B), and the other optional component(s) that is/are to be used as needed, and preferably filtering a resulting mixture through a filter having a pore size of no greater than 0.2 μm.

### Silicon-Containing Film

The silicon-containing film of the other embodiment of the present invention is formed from the composition of the one embodiment of the present invention. Due to being obtained from the composition described above, the silicon-containing film is superior in terms of resistance to etching by an oxygen-based gas and film removability. Furthermore, the silicon-containing film is superior in terms of the embedding property. Thus, the silicon-containing film can be suitably used in a semiconductor substrate-producing process. In particular, the silicon-containing film can be suitably used as the silicon-containing film for use as a resist underlayer film in a multilayer resist process, the silicon-containing film for use as an etching stopper film in a dual damascene process, and the like.

### Method of Forming Silicon-Containing Film

The method of forming a silicon-containing film of the still another embodiment of the present invention includes a step (hereinafter, may be also referred to as “applying step”) of applying a silicon-containing-film-forming composition directly or indirectly on a substrate. In the method of forming a silicon-containing film, the composition of the one embodiment of the present invention, described above, is used as the silicon-containing-film-forming composition.

Due to using the composition described above, the method of forming a silicon-containing film enables forming the silicon-containing film being superior in terms of resistance to etching by an oxygen-based gas and film removability. Furthermore, the method of forming a silicon-containing film enables forming the silicon-containing film being superior in terms of the embedding property.

Hereinafter, each step included in od of forming a silicon-containing film will be described in detail.

Applying Step

In this step, the silicon-containing-film-forming composition is applied directly or indirectly on the substrate. By this step, a coating film of the silicon-containing-film-forming composition is formed on the substrate directly or via another layer. The silicon-containing film is formed by, for example, subjecting the coating film to, typically, heating, thereby allowing for hardening.

The substrate is exemplified by insulating films of silicon oxide, silicon nitride, a silicon oxynitride, a polysiloxane, or the like; resin substrates; and the like. Furthermore, as the substrate, a substrate having a pattern formed thereon with wiring grooves (trenches), plug grooves (vias), or the like may be used.

A procedure for applying the composition is not particularly limited, and for example, spin-coating or the like may be exemplified.

The case of forming the silicon-containing-film-forming composition indirectly on the substrate may be exemplified by a case in which the silicon-containing-film-forming composition is applied on an organic underlayer film such as an anti reflective film, and/or a low-dielectric insulating film which have/has been formed on the substrate.

The heating of the coating film is typically carried out in an ambient atmosphere, but may be carried out in a nitrogen atmosphere. The lower limit of a temperature of the heating is preferably 90° C., more preferably 150° C., and still more preferably 200° C. The upper limit of the temperature s preferably 550° C., more preferably 450° C., and still more preferably 300° C. The lower limit of a time period of heating the coating film is preferably 15 sec, and more preferably 30 sec. The upper limit of the time period of the heating is preferably 1,200 sec, and more preferably 600 sec.

In a case in which the silicon-containing-film-forming composition contains the acid generating agent (C) and the acid generating agent (C) is a radiation-sensitive acid generating agent, formation of the resist underlayer film may be further promoted through a combination of an exposure and heating. Examples of the radioactive ray which can be used for the exposure include: electromagnetic waves such as a visible light ray, an ultraviolet ray (including a far ultraviolet ray), an X-ray, and a γ-ray; particle rays such as an electron beam, a molecular beam, and an ion beam; and the like.

The lower limit of an average thickness of the silicon-containing film to be formed by this step is preferably 1 nm, more preferably 3 nm, and still more preferably 5 nm. The upper limit of the average thickness is preferably 500 nm, more preferably 300 nm, and still more preferably 200 nm. It is to be noted that the average thickness of the silicon-containing film is a value measured by using a spectroscopic ellipsometer (“M2000D,” available from J.A. Woollam Co.).

### Method of Treating Semiconductor Substrate

The method of treating a semiconductor substrate of the yet another embodiment of the present invention includes a step (hereinafter, may be also referred to as “applying step”) of applying a silicon-containing-film-forming composition directly or indirectly on a substrate (a silicon-containing film formed by this step may be also referred to as “silicon-containing film (I)”); and a step (hereinafter, may be also referred to as “removing step”) of removing the silicon-containing film (I) formed in this step, with a removing liquid containing an acid. In the method of treating a semiconductor substrate, the composition of the one embodiment of the present invention is used as the silicon-containing-film-forming composition

The method of treating a semiconductor substrate may further include, as necessary after the step of applying the silicon-containing-film-forming composition, a step (hereinafter, may be also referred to as “organic-underlayer-film-forming step”) of forming an organic underlayer film directly or indirectly on the silicon-containing film (I); a step (hereinafter, may be also referred to as “resist pattern-forming step”) of forming a resist pattern directly or indirectly on the organic underlayer film; and a step (hereinafter, may be also referred to as “etching step”) of etching the organic underlayer film with the resist pattern as a mask.

Furthermore, the method of treating a semiconductor substrate may further include, before the resist pattern-forming step, a step (hereinafter, may be also referred to as “silicon-containing-film-forming step”) of forming a silicon-containing film directly or indirectly on the organic underlayer film (the silicon-containing film formed by this step may be also referred to as “silicon-containing film (II)”).

With regard to the method of treating a semiconductor substrate, due to using the composition of the one embodiment of the present invention, described above, in the applying step thereof, the silicon-containing film (I) is formed having superiority with regard to film removability; thus, in the step of removing the silicon-containing film (I), the silicon-containing film (I) can be easily removed while limiting damage to the substrate. Thus, the method of treating a semiconductor substrate can be suitably adopted in a multilayer resist process and/or a dual damascene process.

Hereinafter, each step included in the method of treating a semiconductor substrate will be described.

Applying Step

In this step, the silicon-containing-film-forming composition is applied directly or indirectly on the substrate. By this step, a coating film of the silicon-containing-film-forming composition is formed on the substrate directly or via another layer. The silicon-containing film (I) is formed by, for example, subjecting the coating film to, typically, heating, thereby allowing for hardening. This step is similar to the applying step in the method of forming a silicon-containing film, described above.

Organic-Underlayer-Film-Forming Step

In this step, after the applying step, and more specifically, after the applying step and before the removing step, the organic underlayer film is formed directly or indirectly on the silicon-containing film. By this step, the organic underlayer film is formed on the silicon-containing film directly or via another layer

The organic underlayer film may be formed by application of an organic-underlayer-film-forming composition, or the like. A procedure of forming the organic underlayer film by application of the organic-underlayer-film-forming composition is exemplified by a procedure of applying the silicon-containing-film-forming composition directly or indirectly on the silicon-containing film (I) to form a coating film; and hardening the coating film by subjecting the coating film to an exposure and/or heating. Examples of the organic-underlayer-film-forming composition include “HM8006,” available from JSR Corporation, and the like. Conditions for the heating and/or the exposure are similar to the conditions for the heating and/or the exposure in the applying step of the method of forming a silicon-containing film.

The case of forming the organic underlayer film indirectly on the silicon-containing film (I) may be exemplified by a case of forming the organic underlayer film on the low-dielectric insulating film which has been formed on the silicon-containing film (I). In other words, the method of treating a semiconductor substrate may further include, after the applying step and before the organic-underlayer-film-forming step, a step of forming the low-dielectric insulating. Examples of the low-dielectric insulating film include a silicon oxide film, and the like.

Silicon-Containing-Film-Forming Step

In this step, before the resist pattern-forming step, and more specifically, after the applying step and before the resist pattern-forming step, the silicon-containing film (II) is formed directly or indirectly on the organic underlayer film. It is to be noted that the silicon-containing film (II) is different from the silicon-containing film (I), described above.

The case of forming the silicon-containing film (II) indirectly on the organic underlayer film is exemplified by a case in which a surface modification film has been formed on the organic underlayer film, and the like. The surface modification film of the organic underlayer film is a film having, for example, an angle of contact with water being different from that of the organic underlayer film.

The silicon-containing film (II) may be formed by applying a silicon-containing-film-forming composition, a chemical vapor deposition (CVD) procedure, atomic layer deposition (ALD), or the like. A procedure of forming the silicon-coating film (II) by applying the composition for silicon-containing film formation is exemplified by: applying the silicon-containing-film-forming composition directly or indirectly on the organic underlayer film to form a coating film; and hardening the coating film by subjecting the coating film to an exposure and/or heating. As a commercially available product of the composition for silicon-containing film formation, for example, “NFC SOG01,” “NFC SOG04,” or “NEC SOG080” (all available from JSR Corporation), or the like may be used. A silicon oxide film, a silicon nitride film, a silicon oxynitride film, or an amorphous silicon film can be formed by the chemical vapor deposition (CVD) procedure or the atom layer deposition (ALD).

Resist Pattern-Forming Step

In this step, the resist pattern is formed directly or indirectly on the organic underlayer film. In carrying out this step, for example, a resist composition may be used, a nanoimprinting procedure may be adopted, or a directed self-assembling composition may be used.

With regard to using the resist composition, specifically, the resist film is formed by: applying the resist composition such that a resultant resist film has a predetermined thickness; and thereafter subjecting the resist composition to prebaking to evaporate the solvent in the coating film.

Examples of the resist composition include: a chemically amplified positive or negative resist composition that contains a radiation-sensitive acid generating agent; a positive resist composition that contains an alkali-soluble resin and a quinone diazide-based photosensitizing agent; a negative resist that contains an alkali-soluble resin and a crosslinking agent; and the like.

The lower limit of a proportion of total components other than the solvent in the resist composition is preferably 0.3% by mass, and more preferably 1% by mass. The upper limit of the proportion is preferably 50% by mass, and more preferably 30% by mass. Moreover, the resist composition is generally used for forming a resist film, for example, after being filtered through a filter with a pore size of no greater than 0.2 μm. It is to be noted that a commercially available resist composition may be used as is in this step.

A procedure for applying the resist composition may be exemplified by, e.g., spin coating and the like. A temperature and time period of prebaking may be appropriately adjusted in accordance with the type and the like the resist composition employed. The lower limit of the temperature is preferably 30° C., and more preferably 50° C., The upper limit of the temperature is preferably 200° C., and more preferably 150° C. The lower limit of the time period is preferably 10 sec; and more preferably 30 sec. The upper limit of the time period is preferably 600 sec, and more preferably 300 sec.

Next, the resist film formed is exposed by selective irradiation with a radioactive ray. The radioactive ray used in the exposure may be appropriately selected in accordance with the type of the radiation-sensitive acid generating agent used in the resist composition, and examples of the radioactive ray include: electromagnetic waves such as visible light rays, ultraviolet rays, far ultraviolet rays, X-rays, and γ-rays; and particle rays such as electron beams, molecular beams, and ion beams. Among these, far ultraviolet rays are preferred, a KrF excimer laser beam (248 nm), an ArF excimer laser beam (193 nm), an F₂ excimer laser beam (wavelength: 157 nm), a Kr₂ excimer laser beam (wavelength: 147 nm), an ArKr excimer laser beam (wavelength: 134 nm), or an extreme ultraviolet ray (wavelength: 13.5 nm, etc.; hereinafter, may be also referred to as “EUV”) is more preferred, and a KrF excimer laser beam, an ArF excimer laser beam, or EUV is still more preferred.

Post-baking may be carried out after the exposure for the purpose of improving a resolution, a pattern profile, developability, and the like. A temperature of the post-baking may be appropriately adjusted in accordance with the type and the like of the resist composition employed; however, the lower limit of the temperature is preferably 50° C., and more preferably 70° C. The upper limit of the temperature is preferably 200° C., and more preferably 150° C. The lower limit of a time period of the post-baking is preferably 10 sec, and more preferably 30 sec. The upper limit of the time period is preferably 600 sec, and more preferably 300 sec.

Next, the resist film exposed is developed with a developer solution to form a resist pattern. The development may be carried out by either development with an alkali, or development with an organic solvent. In the case of the development with an alkali, examples of the developer solution include a basic aqueous solution that contains sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, 1,5-diazabicyclo[4.3.0]-5-nonene, or the like. To the basic aqueous solution, a water-soluble organic solvent, for example, an alcohol such as methanol or ethanol, a surfactant, etc., may be added, each in an appropriate amount. Alternatively, in the case of the development with an organic solvent, examples of the developer solution include various organic solvents exemplified as the solvent (B) of the composition described above, and the like.

A predetermined resist pattern is formed by the development with the developer solution, followed by washing and drying.

Etching Step

In this step, etching of the organic underlayer film is carried out with the resist pattern as a mask. The etching may be conducted once or multiple times. In other cords, the etching may be conducted sequentially with patterns obtained by the etching as masks, and in light of obtaining a pattern having a more favorable shape, the etching is preferably conducted multiple times. An etching procedure may be exemplified by dry etching, wet etching, and the like. By the etching, a pattern is formed on the organic underlayer film.

Furthermore, in the case in which the method of treating a semiconductor substrate includes the silicon-containing-film-forming step, in this step, etching of the silicon-containing film (II) is carried out with the resist pattern as a mask, and by the etching a pattern is formed on the silicon-containing film (H).

The dry etching may be conducted by using, for example, a well-known dry etching apparatus. An etching gas to be used for the dry etching may be appropriately selected depending on the mask pattern, element composition of the film to be etched, and the like. Examples of the etching gas include: fluorine-based gases such as CHF₃, CF₄, C₂F₆, C₃F₈, and SF₆; chlorine-based gases such as Cl₂ and BCl₃; oxygen-based gases such as O₂, O₃, and H₂O; reductive gases such as H₂, NH₃, CO, CO₂, CH₄, C₂H₂, C₂H₄, C₂H₆, C₃H₄, C₃H₆, C₃H₈, HF, HI, HBr, HCl, NO, NH₃, and BCl₃; inert gases such as He, N₂, and Ar; and the like. These gases may be used as a mixture. In the case of etching the substrate using the resist underlayer film pattern as a mask, the fluorine-based gas is typically used.

Removing Step

In this step, the silicon-containing film (I) formed by the applying step is removed with a removing liquid containing an acid (hereinafter, may be also referred to as “removing liquid”).

The removing liquid is exemplified by: a liquid containing an acid and water; a liquid obtained by mixing an acid, hydrogen peroxide, and water; and the like. Examples of the acid include sulfuric acid, hydrofluoric acid, hydrochloric acid, and the like. The removing liquid is preferably a liquid containing hydrofluoric acid and water; a liquid obtained by mixing sulfuric acid, hydrofluoric acid, and water; or a liquid obtained by mixing hydrochloric acid, hydrofluoric acid, and water.

The lower limit of a temperature in the removing step is preferably 20° C., more preferably 40° C., and still more preferably 50° C. The upper limit of the temperature is preferably 300° C., and more preferably 100° C.

The lower limit of a time period of the removing step is preferably 5 sec, and more preferably 30 sec. The upper limit of the time period is preferably 10 min, and more preferably 180 sec.

### EXAMPLES

Hereinafter, Examples are described. It is to be noted that the following Examples merely illustrate typical Examples of the embodiments of the present invention, and the Examples should not be construed to narrow the scope of the present invention.

In the present Examples, measurement of a weight average molecular weight (Mw) of the compound (a) and the compound (A), measurement of a concentration of each solution of the compound (A), and measurement of an average thickness of each film were carried out by the following methods.

Weight Average Molecular Weight (Mw)

Measurements of the weight average molecular weights of compounds (a-1) to (a-3) and compound (A) were carried out by gel permeation chromatography (GPC) by using GPC columns (“G2000 HXL”×2, “G3000 HXI,”×1, and “G4000 HXL”×1, all available from Tosoh Corporation) under the following conditions.

elution solvent: tetrahydrofuran (Wako Pure Chemical industries, Inc.

flow rate: 1.0 mL/min

sample concentration: 1.0% by mass

amount of injected sample: 100 uL

column temperature: 40° C.

detector: differential refractometer

standard substance: mono-dispersed polystyrene

Concentration of Solution of Compound (A)

The concentration (% by mass) of the solution of the compound (A) was determined by: baking 0.5 g of the solution of the compound (A) at 250° C. for 30 min; measuring a mass of a residue thus obtained; and dividing the mass of the residue by the mass of the solution of the compound (A).

Average Thickness of Film

The average thickness of the film was measured by using a spectroscopic ellipsometer (“M2000D,” available from J. A. Woollam Co.).

### Synthesis of Compounds (a-1) to (a-3)

Monomers (hereinafter, may be also referred to as “monomer (H-1),” “monomer (S-1),” and “monomer (S-2)”) used for synthesis in Synthesis Examples 1 to 3 are presented below.

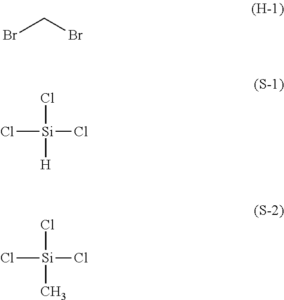

### Synthesis Example 1-1: Synthesis of Compound (a-1)

Into a nitrogen-substituted reaction vessel, 5.83 g of magnesium and 11 g of tetrahydrofuran were charged, and the mixture was stirred at 20° C. Next, 17.38 g of the monomer (H-1) and 13.54 g of the monomer (S-1) (molar ratio: 50/50 (mol %)) were dissolved in 111 g of tetrahydrofuran to prepare a monomer solution. The internal temperature of the reaction vessel was adjusted to 20° C., and the monomer solution was added dropwise thereto over 1 hour with stirring. A time point of completion of the dropwise addition was defined as a start time of the reaction, and the reaction was allowed at 40° C. for 1 hr, and then at 60° C. for 3 hrs. After completion of the reaction, 6 g of tetrahydrofuran was added thereto, and the mixture was cooled to no greater than 10° C. to give a polymerization reaction liquid. Next, 30.36 g of triethylamine was added to the polymerization reaction liquid, and then 9.61 g of methanol was added dropwise over 10 min with stirring. A time point of completion of the dropwise addition was defined as a start time of the reaction, and the reaction was allowed at 20° C. for 1 hr. The reaction liquid was charged into 220 g of diisopropyl ether, and a salt thus precipitated was filtered out. Next, tetrahydrofuran, diisopropyl ether, triethylamine, and methanol in the filtrate were removed by using an evaporator. A thus resulting residue was charged into 50 g of diisopropyl ether, and a salt thus precipitated was filtered out. Then, removing diisopropyl ether from the filtrate using the evaporator and adding methyl isobutyl ketone to a resulting filtrate gave 128 g of a methyl isobutyl ketone solution of the compound (a-1). The Mw of the compound (a-1) was 1,000.

### Synthesis Examples 1-2 to 1-5: Synthesis of Compounds (a-2) to (a-5)

Methyl isobutyl ketone solutions of compounds (a-2) to (a-5) were obtained by a similar operation to that of Synthesis Example 1 except that monomers of the types and in the proportions shown in Table 1 below were used. The weight average molecular weights (Mw) of the resulting compounds (a) are shown together in Table 1. It is to be noted that in Table 1, “−” indicates that the corresponding monomer was not used.

TABLE 1

| | | Amount of each | | | |
|---|---|---|---|---|---|
| | | monomer charged (mol %) | | | |
| — | Compound | H-1 | S-1 | S-2 | Mw |
| Synthesis | a-1 | 50 | 50 | — | 1,000 |
| Example 1-1 | | | | | |
| Synthesis | a-2 | 50 | 35 | 15 | 800 |
| Example 1-2 | | | | | |
| Synthesis | a-3 | 50 | — | 50 | 700 |
| Example 1-3 | | | | | |
| Synthesis | a-4 | 50 | 45 | 5 | 900 |
| Example 1-4 | | | | | |
| Synthesis | a-5 | 50 | 40 | 10 | 900 |
| Example 1-5 | | | | | |

### Synthesis of Compound (A)

Monomers (hereinafter, may be also referred to as “monomer (M-1)” to “monomer (M-10)”) used for synthesis in Examples 1-1 to 1-22 and Comparative Examples 1-1 to 1-4 are presented below. Furthermore, in the following Examples 1-1 to 1-22 and. Comparative Examples 1-1 to 1-4, the term “mol %” means a value, provided that the total mol number of the silicon atoms in the compounds (a-1) to (a-3) and the monomers (M-1) to (M-10) used was 100 mol %.

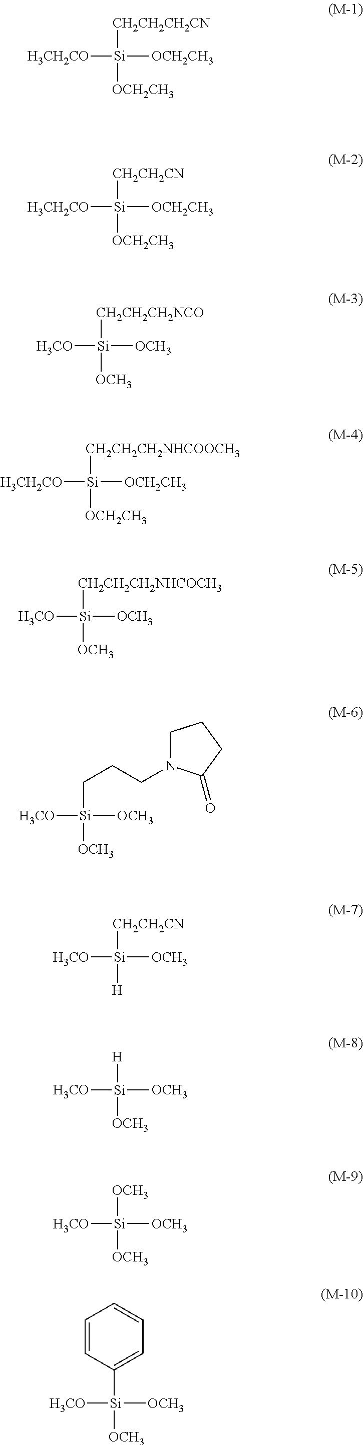

### Example 1-1: Synthesis of Compound (A-1)

Into a reaction vessel were added 128 g of the methyl isobutyl ketone solution of the compound (a-1) obtained in Synthesis Example 1 described above, 23.15 g of the monomer (M-1), and 21.43 g of methanol. The internal temperature of the reaction vessel was adjusted to 50° C., and 22.35 g of a 3.2% by mass aqueous oxalic acid solution was added dropwise thereto over 20 min with stirring. A time point of completion of the dropwise addition was defined as a start time of the reaction, and the reaction was allowed at 80° C. for 4 hrs, and then the internal temperature of the reaction vessel was lowered to no greater than 30° C. Next, to the reaction vessel were added 171 g of methyl isobutyl ketone and 515 g of water, and then extraction was conducted by liquid separation. To an organic layer thus obtained was added 343 g of propylene glycol monomethyl ether acetate, and then water, methyl isobutyl ketone, alcohols generated by the reaction, and excess propylene glycol monomethyl ether acetate were removed by using an evaporator. Next, to a thus obtained solution was added 17.14 g of trimethyl orthoformate as a dehydrating agent, a reaction was allowed at 40° C. for 1 hr, and then the internal temperature of the reaction vessel was lowered to no greater than 30° C. Alcohols generated by the reaction, esters, trimethyl orthoformate, and excess propylene glycol monomethyl ether acetate were removed by using the evaporator to give a propylene glycol monomethyl ether acetate solution of the compound (A-1). The Mw of the compound (A-1) was 2,300. The concentration of the propylene glycol monomethyl ether acetate solution of the compound (A-1) was 10% by mass.

### Examples 1-2 to 1-14, Comparative Examples 1-1 to 1-2, and Reference Examples 1-1 to 1-2: Synthesis of Compounds (A-2) to (A-14), Compounds (AJ-1) to (AJ-2), and Compounds (AJ-5) to (AJ-6)

Propylene glycol monomethyl ether acetate solutions of compounds (A-2) to (A-14), (AJ-1) to (AJ-2), and (AJ-5) to (AJ-6) were obtained by a similar operation to that of Example 1-1 except that compounds and monomers of the types and in the proportions shown in Table 2 below were used. It is to be noted that in Table 2 below, “−” indicates that the corresponding monomer was not used. With regard to the compounds (A) obtained, concentrations (% by mass) thereof in the solutions, and the weight average molecular weights (Mw) thereof are shown together in Table 2.

### Example 1-15: Synthesis of Compound (A-15)

Into a reaction vessel were added 23.02 of the compound (M-1), 12.16 g of the compound (M-8), 104 g of methyl isobutyl ketone, and 21.43 g of methanol. The internal temperature of the reaction vessel was adjusted to 50° C., and 33.34 g of a 3.2% by mass aqueous oxalic acid solution was added dropwise thereto over 20 min with stirring. A time point of completion of the dropwise addition was defined as a start time of the reaction, and the reaction was allowed at 80° C. for 4 hrs, and then the internal temperature of the reaction vessel was lowered to no greater than 30° C. Next, to the reaction vessel were added 171 g of methyl isobutyl ketone and 515 g of water, and then extraction was conducted by liquid separation. To an organic layer thus obtained was added 343 g of propylene glycol monoethyl ether, and then water, diisopropyl ether, alcohols generated by the reaction, and excess propylene glycol monoethyl ether were removed by using an evaporator to give a propylene glycol monoethyl ether solution of the compound (A-15). The Mw of the compound (A-15) was 2,500. The concentration of the propylene glycol monomethyl ether solution of the compound (A-15) was 10% by mass.

### Examples 1-16 to 1-22 and Comparative Examples 1-3 to 1-4: Synthesis of Compounds (A-16) to (A-22) and Compounds (AJ-3) to (AJ-4)

Propylene glycol monoethyl ether solutions of compounds (A-16) to (A-22) and (AJ-3) to (AJ-4) were obtained by a similar operation to that of Example 1-15 except that monomers of the types and in the proportions shown in Table 2 below were used. It is to be noted that in Table 2 below, “−” indicates that the corresponding monomer was not used. With regard to the compounds (A) obtained, concentrations (% by mass) thereof in the solutions, and the weight average molecular weights (Mw) thereof are shown together in Table 2.

TABLE 2

| | (A) | Amounts of compound and each monomer charged (Si mol %) | | | | | | | | | | | | Concentration | |
|---|---|---|---|---|---|---|---|---|---|---|---|---|---|---|---|
| — | Compound | compound | | M-1 | M-2 | M-3 | M-4 | M-5 | M-6 | M-7 | M-8 | M-9 | M-10 | (% by mass) | Mw |
| Example 1-1 | A-1 | a-1 | 50 | 50 | — | — | — | — | — | — | — | — | — | 10 | 2,300 |
| Example 1-2 | A-2 | a-1 | 90 | 10 | — | — | — | — | — | — | — | — | — | 10 | 2,600 |
| Example 1-3 | A-3 | a-1 | 10 | 90 | — | — | — | — | — | — | — | — | — | 10 | 2,000 |
| Example 1-4 | A-4 | a-1 | 50 | — | 50 | — | — | — | — | — | — | — | — | 10 | 2,200 |
| Example 1-5 | A-5 | a-1 | 50 | — | — | 50 | — | — | — | — | — | — | — | 10 | 2,100 |
| Example 1-6 | A-6 | a-1 | 50 | — | — | — | 50 | — | — | — | — | — | — | 10 | 2,300 |
| Example 1-7 | A-7 | a-1 | 50 | — | — | — | — | 50 | — | — | — | — | — | 10 | 2,200 |
| Example 1-8 | A-8 | a-1 | 50 | — | — | — | — | — | 50 | — | — | — | — | 10 | 2,300 |
| Example 1-9 | A-9 | a-2 | 60 | 40 | — | — | — | — | — | — | — | — | — | 10 | 2,200 |
| Example 1-10 | A-10 | a-2 | 60 | — | 40 | — | — | — | — | — | — | — | — | 10 | 2,100 |
| Example 1-11 | A-11 | a-2 | 60 | — | — | 40 | — | — | — | — | — | — | — | 10 | 2,000 |
| Example 1-12 | A-12 | a-2 | 60 | — | — | — | 40 | — | — | — | — | — | — | 10 | 2,200 |
| Example 1-13 | A-13 | a-2 | 60 | — | — | — | — | 40 | — | — | — | — | — | 10 | 2,100 |
| Example 1-14 | A-14 | a-2 | 60 | — | — | — | — | | 40 | — | — | — | — | 10 | 2,200 |
| Example 1-15 | A-15 | — | — | 50 | — | — | — | — | — | — | 50 | — | — | 10 | 2,500 |
| Example 1-16 | A-16 | — | — | — | 50 | — | — | — | — | — | 50 | — | — | 10 | 2,400 |
| Example 1-17 | A-17 | — | — | — | — | 50 | — | — | — | — | 50 | — | — | 10 | 2,300 |
| Example 1-18 | A-18 | — | — | — | — | — | 50 | — | — | — | 50 | — | — | 10 | 2,500 |
| Example 1-19 | A-19 | — | — | — | — | — | — | 50 | — | — | 50 | — | — | 10 | 2,400 |
| Example 1-20 | A-20 | — | — | — | — | — | — | — | 50 | — | 50 | — | — | 10 | 2,500 |
| Example 1-21 | A-21 | — | — | 15 | — | — | — | — | — | — | 75 | — | 10 | 10 | 2,700 |
| Example 1-22 | A-22 | — | — | — | — | — | — | — | — | 100 | — | — | — | 10 | 2,200 |
| Comparative | AJ-1 | a-1 | 100 | — | — | — | — | — | — | — | — | — | — | 10 | 2,800 |
| Example 1-1 | | | | | | | | | | | | | | | |
| Comparative | AJ-2 | a-3 | 100 | — | — | — | — | — | — | — | — | — | — | 10 | 1,700 |
| Example 1-2 | | | | | | | | | | | | | | | |
| Comparative | AJ-3 | — | — | — | — | — | — | — | — | — | 90 | — | 10 | 10 | 2,000 |
| Example 1-3 | | | | | | | | | | | | | | | |
| Comparative | AJ-4 | — | — | 15 | — | — | — | — | — | — | — | 75 | 10 | 10 | 2,250 |
| Example 1-4 | | | | | | | | | | | | | | | |
| Reference | AJ-5 | a-4 | 100 | — | — | — | — | — | — | — | — | — | — | 10 | 2,000 |
| Example 1-1 | | | | | | | | | | | | | | | |
| Reference | AJ-6 | a-5 | 100 | — | — | — | — | — | — | — | — | — | — | 10 | 2,000 |
| Example 1-2 | | | | | | | | | | | | | | | |

### Preparation of Composition

Components other than the compound (A) used in preparing each composition are shown below. It is to be noted that in Examples 2-1 to 2-24, Comparative Examples 2-1 to 2-4, and Reference Examples 2-1 to 2-2 below, unless otherwise specified particularly, the term “parts by mass” means a value, provided that the total mass of the components used was 100 parts by mass.

(B) Solvent

B-1: propylene glycol monomethyl ether acetate

B-2: propylene glycol monoethyl ether

(C) Acid Generating Agent

C-1: a compound represented by the following formula (C-1)

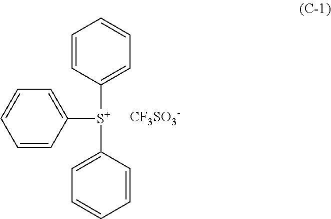

(D) Orthoester

D-1: trimethyl orthoformate

### Example 2-1: Preparation of Composition (J-1)

Composition (J-1) was prepared by: mixing 1.0 parts by mass (not including the solvent) of (A-1) as the compound (A), 0.3 parts by mass of (C-1) as the acid generating agent (C), and 98.7 parts by mass of (B-1) as the solvent (B) (including the solvent (B-1) contained in the solution of the compound (A)); and filtering a resulting solution through a filter having a pore size of 0.2 μm.

### Examples to 2-24, Comparative Examples 2-1 to 2-4, and Reference Examples 2-1 to 2-2: Preparation of Compositions (J-2) to (J-24) and (j-1) to (j-6)

Compositions (J-2) to (J-24) of Examples 2-2 to 2-24 and compositions (j-1) to (j-6) of Comparative Examples 2-1 to 2-4 were prepared by a similar operation to that of Example 2-1 except that for each component, the type and content shown in Table 3 below were used. In the Table 3 below, “−” indicates that the corresponding component was not used.

### Evaluations

The compositions described above were evaluated with regard to resistance to etching by an oxygen-based gas, film removability (removability by hydrogen fluoride (HF) liquid), and the embedding property by the following methods. The results of the evaluations are shown in Table 3 below.

Resistance to Etching by Oxygen-Based Gas

Each composition prepared as described above was applied on an 8-inch silicon wafer by spin-coating using a spin-coater (“CLEAN TRACK ACT 8,” available from Tokyo Electron Limited), and thereafter heating was conducted in an ambient atmosphere at 220° C. for 60 sec, followed by cooling at 23° C. for 30 sec to form a silicon-containing film having an average thickness of 100 nm. The substrate having the silicon-containing film formed thereon was subjected to an etching treatment by using an etching apparatus (“Tactras-Vigus” available from Tokyo Electron Limited), under conditions involving O₂=400 sccm, PRESS.=25 mT, HF RF (radiofrequency power for plasma production)=200 W, LF RF (radiofrequency power for bias)=0 W, DCS=0 V, and RDC (flow rate percentage at gas center)=50%, for 60 sec. An etching rate (nm/min) was calculated from average film thicknesses of the silicon-containing film before and after the treatment, and the resistance to etching by the oxygen-based gas was evaluated. The resistance to etching by the oxygen-based gas was evaluated to be: “A” (favorable) in a case in which the etching rate was less than 5.0 nm/min; or “B” (unfavorable) in a case in which the etching rate was no less than 5.0 nm/min.

Film Removability (Removability by Hydrogen Fluoride (HF) Liquid)

Each composition prepared as described above was applied on an 8-inch silicon wafer, a silicon dioxide film having an average thickness of 500 nm being formed thereon, by spin-coating using the spin-coater, and thereafter heating was conducted in an ambient atmosphere at 220° C. for 60 sec, followed by cooling at 23° C. for 30 sec to form a silicon-containing film having an average thickness of 10 nm. The substrate having the silicon-containing film formed thereon was immersed in an aqueous mixed liquid which was heated to 50° C., the aqueous mixed liquid having a ratio of 50% by mass hydrofluoric acid to water being 1/5 (volume ratio). Thereafter, the substrate was immersed in water and then dried. A cross section of a thus obtained substrate was observed using a field emission scanning electron microscope (“SU8220,” available from Hitachi High-Technologies Corporation), and was evaluated to be: “A” (favorable) in a case of the silicon-containing film not remaining; or “B” (unfavorable) in a case of the silicon-containing film remaining.

Embedding Property

On a silicon nitride substrate having a trench pattern with a depth of 200 nm and a width of 30 nm formed thereon, each composition prepared as described above was applied with the spin coater by way of a spin-coating procedure. A rotational speed for the spin coating was the same as that in the case of forming the silicon-containing film having the average thickness of 100 nm on the 8-inch silicon wafer in the evaluation of the “Resistance to Etching by Oxygen-Based Gas,” described above. Next, heating was carried out in an ambient atmosphere at 250° C. for 60 sec, followed by cooling at 23° C. for 30 sec to give the substrate having a silicon-containing film formed thereon. The presence/absence of an embedding defect (void) was confirmed on a cross section of the substrate thus obtained by using a field emission scanning electron microscope (“SU8220,” available from Hitachi High-Technologies Corporation). The embedding property was evaluated to be: “A” (favorable) in a case of no embedding defect being observed; or “B” (unfavorable) in a case of the defect being observed.

### Preparation of Resist Composition

A resist composition was prepared as in the following. A resist composition (R-1) was obtained by: mixing 100 parts by mass of a polymer having a structural unit (1) derived from 4-hydroxystyrene, a structural unit (2) derived from styrene, and a structural unit (3) derived from 4-t-butoxystyrene (proportion of each structural unit contained: (1)/(2)/(3)=65/5/30 (mol %)), 2.5 parts by mass of triphenylsulfonium salicylate as a radiation-sensitive acid generating agent, and 4,400 parts by mass of ethyl lactate and 1,900 parts by mass of propylene glycol monomethyl ether acetate each as the solvent; and filtering a thus resulting solution through a filter having a pore size of 0.2 μm.

### Evaluations

The resolution upon exposure to an extreme ultraviolet ray was evaluated in accordance with the following method. The results of the evaluations are shown in Table 3 below.

Resolution (Resolution Upon Exposure to Extreme Ultraviolet Ray)

A material for organic underlayer film formation (“HM8006,” available from JSR Corporation) was applied on an 12-inch silicon wafer by spin-coating using a spin-coater (“CLEAN TRACK ACT 12,” available from Tokyo Electron Limited), and thereafter heating was conducted at 250° C. for 60 sec to form an organic underlayer film having an average thickness of 100 nm. Each composition prepared as described above was applied on the organic underlayer film, and subjected to heating at 220° C. for 60 sec, followed by cooling at 23° C. for 30 sec to form a silicon-containing film having an average thickness of 10 nm. The resist composition (R-1) was applied on each silicon-containing film formed as described above, and heating was conducted at 130° C. for 60 sec, followed by cooling at 23° C. for 30 sec to form a resist film having an average thickness of 50 nm. Next, the resist film was irradiated with an extreme ultraviolet ray using an EUV scanner (“TWINSCAN NXE 3300B,” available from ASML Co. (NA=0.3; Sigma=0.9; quadrupole illumination, with a 1:1 line and space mask having a line width of 25 nm in terms of a dimension on wafer)). After the irradiation with the extreme ultraviolet ray, the substrate was heated at 110° C. for 60 sec, followed by cooling at 23° C. for 60 sec. Thereafter, a development was carried out using a 2.38% by mass aqueous TMAH solution (20° C. to 25° C.) with a puddle procedure, followed by washing with water and drying to give a substrate for evaluation having a resist pattern formed thereon. For line-width measurement and observation of the resist pattern on the substrate for evaluation, a scanning electron microscope (“CG-4000,” available from Hitachi High-Technologies Corporation) was used. On the substrate for evaluation, an exposure dose at which a 1:1 line and space pattern with a line width of 25 nm was formed was defined as an optimum exposure dose. With regard to the recessed portions of the pattern formed at the optimum exposure dose, the resolution was evaluated to be: “A” (favorable) in a case of no residue being confirmed on the resist film; or “B” (unfavorable) in a case of residue being confirmed on the resist film.

TABLE 3

| | | | | | | | | | | Evaluations | | | |
|---|---|---|---|---|---|---|---|---|---|---|---|---|---|
| | | | | | | (C) Acid | | | | | film | | |
| | | (A) | | (B) | | generating | | (D) | | | remo- | | |
| | | Compound | | Solvent | | agent | | Orthoester | | oxygen- | vability | | |
| | | | amount | | amount | | amount | | amount | based | (remo- | | |
| | | | (parts | | (parts | | (parts | | (parts | gas | vability | em- | |
| | Com- | | by | | by | | by | | by | etching | by HF | bedding | reso- |
| — | position | Type | mass) | type | mass) | type | mass) | type | mass) | resistance | liquid) | property | lution |
| Example 2-1 | J-1 | A-1 | 1.0 | B-1 | 98.7 | C-1 | 0.3 | — | — | A | A | A | A |
| Example 2-2 | J-2 | A-2 | 1.0 | B-1 | 98.7 | C-1 | 0.3 | — | — | A | A | A | A |
| Example 2-3 | J-3 | A-3 | 1.0 | B-1 | 98.7 | C-1 | 0.3 | — | — | A | A | A | A |
| Example 2-4 | J-4 | A-4 | 1.0 | B-1 | 98.7 | C-1 | 0.3 | — | — | A | A | A | A |
| Example 2-5 | J-5 | A-5 | 1.0 | B-1 | 98.7 | C-1 | 0.3 | — | — | A | A | A | A |
| Example 2-6 | J-6 | A-6 | 1.0 | B-1 | 98.7 | C-1 | 0.3 | — | — | A | A | A | A |
| Example 2-7 | J-7 | A-7 | 1.0 | B-1 | 98.7 | C-1 | 0.3 | — | — | A | A | A | A |
| Example 2-8 | J-8 | A-8 | 1.0 | B-1 | 98.7 | C-1 | 0.3 | — | — | A | A | A | A |
| Example 2-9 | J-9 | A-9 | 1.0 | B-1 | 98.7 | C-1 | 0.3 | — | — | A | A | A | A |
| Example 2-10 | J-10 | A-10 | 1.0 | B-1 | 98.7 | C-1 | 0.3 | — | — | A | A | A | A |
| Example 2-11 | J-11 | A-11 | 1.0 | B-1 | 98.7 | C-1 | 0.3 | — | — | A | A | A | A |
| Example 2-12 | J-12 | A-12 | 1.0 | B-1 | 98.7 | C-1 | 0.3 | — | — | A | A | A | A |
| Example 2-13 | J-13 | A-13 | 1.0 | B-1 | 98.7 | C-1 | 0.3 | — | — | A | A | A | A |
| Example 2-14 | J-14 | A-14 | 1.0 | B-1 | 98.7 | C-1 | 0.3 | — | — | A | A | A | A |
| Example 2-15 | J-15 | A-15 | 1.0 | B-2 | 99.0 | — | — | — | — | A | A | A | A |
| Example 2-16 | J-16 | A-16 | 1.0 | B-2 | 99.0 | — | — | — | — | A | A | A | A |
| Example 2-17 | J-17 | A-17 | 1.0 | B-2 | 99.0 | — | — | — | — | A | A | A | A |
| Example 2-18 | J-18 | A-18 | 1.0 | B-2 | 99.0 | — | — | — | — | A | A | A | A |
| Example 2-19 | J-19 | A-19 | 1.0 | B-2 | 99.0 | — | — | — | — | A | A | A | A |
| Example 2-20 | J-20 | A-20 | 1.0 | B-2 | 99.0 | — | — | — | — | A | A | A | A |
| Example 2-21 | J-21 | A-21 | 1.0 | B-2 | 99.0 | — | — | — | — | A | A | A | A |
| Example 2-22 | J-22 | A-22 | 1.0 | B-2 | 99.0 | — | — | — | — | A | A | A | A |
| Example 2-23 | J-23 | A-1 | 1.0 | B-1 | 95.7 | C-1 | 0.3 | D-1 | 3.0 | A | A | A | A |
| Example 2-24 | J-24 | A-1 | 1.0 | B-1 | 99.0 | — | — | — | — | A | A | A | A |
| Comparative | j-1 | AJ-1 | 1.0 | B-1 | 98.7 | C-1 | 0.3 | — | — | A | B | B | A |
| Example 2-1 | | | | | | | | | | | | | |
| Comparative | j-2 | AJ-2 | 1.0 | B-1 | 98.7 | C-1 | 0.3 | — | — | B | B | B | A |
| Example 2-2 | | | | | | | | | | | | | |
| Comparative | j-3 | AJ-3 | 1.0 | B-2 | 99.0 | — | — | — | — | A | B | B | A |
| Example 2-3 | | | | | | | | | | | | | |
| Comparative | j-4 | AJ-4 | 1.0 | B-2 | 99.0 | — | — | — | — | B | A | A | A |
| Example 2-4 | | | | | | | | | | | | | |
| Reference | j-5 | AJ-5 | 1.0 | B-1 | 99.0 | — | — | — | — | A | B | B | A |
| Example 2-1 | | | | | | | | | | | | | |
| Reference | j-6 | AJ-6 | 1.0 | B-1 | 99.0 | — | — | — | — | A | B | B | A |
| Example 2-2 | | | | | | | | | | | | | |

As is seen from the results shown in Table 3, when compared to the silicon-containing films formed from the compositions of the Comparative Examples, the silicon-containing films formed from the compositions of the Examples were favorable with regard to resistance to etching by an oxygen-based gas. Furthermore, when compared to the silicon-containing films formed from the compositions of the Comparative Examples, the silicon-containing films formed from the compositions of the Examples were favorable with regard to film removability and the embedding property.

The composition of the one embodiment of the present invention enables forming a silicon-containing film which is superior in terms of resistance to etching by an oxygen-based gas. Furthermore, the composition enables forming the silicon-containing film which is superior in terms of removability of the silicon-containing film (film removability) by a removing liquid containing an acid. The silicon-containing film of the other embodiment of the present invention is superior in terms of resistance to etching by an oxygen-based gas and film removability. The method of forming a silicon-containing film of the still another embodiment of the present invention enables forming a silicon-containing film which is superior in terms of resistance to etching by an oxygen-based gas and film removability. The method of treating a semiconductor substrate of the yet another embodiment of the present invention enables easily removing a silicon-containing film in a removing step thereof, while limiting damage to layers under the silicon-containing film due to etching. Thus, these can be suitably used in production of a silicon substrate, and the like.

Obviously, numerous modifications and variations of the present invention are possible in light of the above teachings. It is therefore to be understood that within the scope of the appended claims, the invention may be practiced otherwise than as specifically described herein.

What is claimed is:

1. A composition comprising:
at least one compound selected from the group consisting of:
a first compound which comprises a first structural unit comprising a Si—H bond, and a second structural unit represented by formula (2), and
a second compound which comprises the second structural unit represented by the formula (2); and
a solvent, 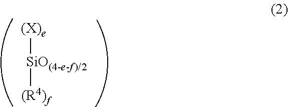
wherein, in the formula (2), X represents a monovalent organic group having 1 to 20 carbon atoms which comprises a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; and f is an integer of 0 to 2; wherein in a case in which f is 2; two R⁴s are identical or different from each other, and wherein a sum of e and f is no greater than 3, wherein
in the case in which the at least one compound is the second compound, f is 1 or 2, and at least one R⁴ represents a hydrogen atom.

2. The composition according to claim 1, wherein the first structural unit is at least one selected from the group consisting of: a structural unit represented by formula (1-1); and a structural unit represented by formula (1-2): 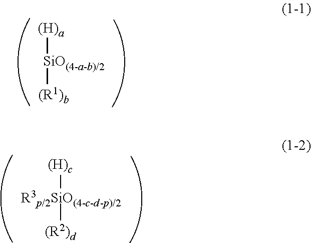
wherein; in the formula (1-1), a is an integer of 1 to 3; R¹ represents a monovalent organic group having 1 to 20 carbon atoms, or a hydroxy group or a halogen atom; and b is an integer of 0 to 2, wherein in a case in which b is 2, two R¹s are identical or different from each other, and wherein a sum of a and b is no greater than 3, and
in the formula (1-2), c is an integer of 1 to 3; R² represents a monovalent organic group having 1 to 20 carbon atoms, or a hydroxy group or a halogen atom; d is an integer of 0 to 2, wherein in a case in which d is 2, two R²s are identical or different from each other; R³ represents a substituted or unsubstituted divalent hydrocarbon group having 1 to 20 carbon atoms which bonds to two silicon atoms; and p is an integer of 1 to 3, wherein in a case in which p is no less than 2, a plurality of R³s are identical or different from each other, and wherein a sum of c, d, and p is no greater than 4.

3. The composition according to claim 1, wherein the compound further comprises at least one third structural unit selected from the group consisting of: a structural unit represented by formula (3-1); and a structural unit represented by formula (3-2): 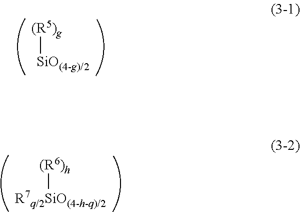
wherein, in the formula (3-1), R⁵ represents a monovalent organic group having 1 to 20 carbon atoms, or a hydroxy group or a halogen atom; and g is an integer of 1 to 3, wherein in a case in which g is no less than 2, a plurality of R⁵s are identical or different from each other, and
in the formula (3-2), R⁶ represents a monovalent organic group having 1 to 20 carbon atoms, or a hydroxy group or a halogen atom; h is 1 or 2, wherein in a case in which h is 2, two R⁶s are identical or different from each other; R⁷ represents a substituted or unsubstituted divalent hydrocarbon group having 1 to 20 carbon atoms which bonds to two silicon atoms; and q is an integer of 1 to 3, wherein in a case in which q is no less than 2, a plurality of R⁷s are identical or different from each other, and wherein a sum of h and q is no greater than 4.

4. The composition according to claim 1, wherein the monovalent organic group having 1 to 20 carbon atoms which comprises a nitrogen atom and is represented by X in the formula (2), is a group which comprises a cyano group, a group which comprises an isocyanate group, or a group represented by formula (2-3) or (2-4): 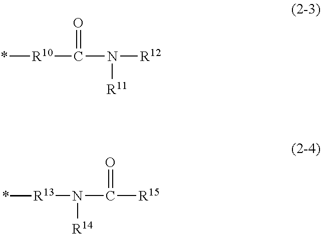
wherein, in the formulae (2-3) and (2-4), * denotes a binding site to the silicon atom in the formula (2),
in the formula (2-3), R¹⁰ represents a single bond or a divalent organic group having 1 to 20 carbon atoms; and with regard to R¹¹ and R¹², R¹¹ represents a hydrogen atom or a monovalent hydrocarbon group having 1 to 20 carbon atoms, and R¹² represents a monovalent organic group having 1 to 20 carbon atoms, or R¹¹ and R¹² taken together represent a ring structure having 4 to 20 ring atoms together with the atom chain to which R¹¹ and R¹² bond, and
in the formula (2-4), R¹³ represents a single bond or a divalent organic group having 1 to 20 carbon atoms; and with regard to R¹⁴ and R¹⁵, R¹⁴ represents a hydrogen atom or a monovalent hydrocarbon group having 1 to 20 carbon atoms, and R¹⁵ represents a monovalent organic group having 1 to 20 carbon atoms, or R¹⁴ and R¹⁵ taken together represent a ring structure having 4 to 20 ring atoms together with the atom chain to which R¹⁴ and R¹⁵ bond.

5. The composition according to claim 4, wherein the group which comprises a cyano group is represented by formula (2-1): 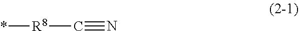
wherein in the formula (2-1), R⁹ represents a single bond or a divalent organic group having 1 to 20 cat bon atoms; and * denotes a binding site to the silicon atom in the formula (2).

6. The composition according to claim 4, wherein the group which comprises an isocyanate group is represented by formula) 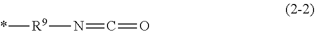
wherein, in the formula (2-2) R⁹ represents a single bond or a divalent organic group having 1 to 20 carbon atoms; and * denotes a binding site to the silicon atom in the formula (2).

7. The composition according to claim 1, wherein a proportion of the second structural unit with respect to total structural units constituting the compound is no less than 5 mol % and no greater than 95 mol %.

8. The composition according to claim 2, wherein the composition comprises the first compound, and the first compound is represented by the formula (1-2).

9. The composition according to claim 1, which is suitable for forming a silicon-containing film.

10. The composition according to claim 8, which is suitable for a semiconductor substrate-producing process.

11. A silicon-containing film formed from the composition according to claim 1.

12. A method of forming a silicon-containing film, the method comprising:
applying a silicon-containing-film-forming composition directly or indirectly on a substrate, wherein
the silicon-containing-film-forming composition comprises:
at least one compound selected from the group consisting of:
a first compound which comprises a first structural unit comprising a Si—H bond, and a second structural unit represented by formula (2); and
a second compound which comprises the second structural unit represented by the formula (2); and
a solvent, 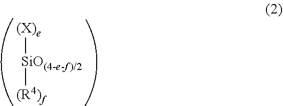
wherein, in the formula (2), X represents a monovalent organic group having 1 to 20 carbon atoms which comprises a nitrogen atom; e is an integer of 1 to 3, wherein in a case in which e is no less than 2, a plurality of Xs are identical or different from each other; R⁴ represents a monovalent organic group having 1 to 20 carbon atoms, or a hydroxy group, a hydrogen atom, or a halogen atom; and f is an integer of 0 to 2, wherein in a case in which f is 2, two R⁴s are identical or different from each other, and wherein a sum of e and f is no greater than 3, wherein
in the case in which the at least one compound is the second compound, f is 1 or 2, and at least one R⁴ represents a hydrogen atom.

13. A method of treating a semiconductor substrate, the method comprising:
applying a silicon-containing-film-forming composition directly or indirectly on a substrate to form a silicon-containing film; and
removing the silicon-containing film, with a removing liquid comprising an acid, wherein
the silicon-containing-film-forming composition comprises:
at least one compound selected from the group consisting of:
a first compound which comprises a first structural unit comprising a Si—H bond, and a second structural unit represented by formula (2); and
a second compound which comprises the second structural unit represented by the formula (2); and
a solvent, 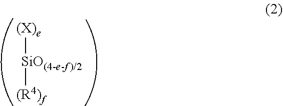
wherein, n the formula (2), X represents a monovalent organic group having 1 to 20 carbon atoms which comprises a nitrogen atom; e is an integer of 1 to 3, wherein in a case in which e is no less than 2, a plurality of Xs are identical or different from each other; R⁴ represents a monovalent organic group having 1 to 20 carbon atoms; or a hydroxy group, a hydrogen atom, or a halogen atom; and f is an integer of 0 to 2, wherein in a case in which f is 2, two R⁴s are identical or different from each other, and wherein a sum of e and f is no greater than 3, wherein
in the case in which the at least one compound is the second compound, f is 1 or 2, and at least one R⁴ represents a hydrogen atom.

14. The method according to claim 13, which comprises, after the applying:
forming an organic underlayer film directly or indirectly on the silicon-containing film;
forming a resist pattern directly or indirectly on the organic underlayer film; and
etching the organic underlayer film with the resist pattern as a mask.

15. The method according to claim 13, wherein the removing liquid comprising an acid is a liquid comprising an acid and water; or a liquid obtained by mixing an acid, hydrogen peroxide, and water.
